(19) United States
(12) Patent Application Publication
(10) Pub. No.: US 2008/0153229 A1
(43) Pub. Date: Jun. 26, 2008

(54) METHOD FOR FABRICATING FLASH MEMORY DEVICE

(76) Inventors: Sang-Il Hwang, Gangwon-do (KR); Jeong-Yel Jang, Suwon-si (KR)

Correspondence Address: SHERR & NOURSE, PLLC, 620 HERNDON PARKWAY, SUITE 200, HERNDON, VA, 20170, US

(21) Appl. No.: 11/945,100

(22) Filed: Nov. 26, 2007

(30) Foreign Application Priority Data
Dec. 21, 2006 (KR) 10-2006-0131514

(51) Int. Cl. H01L 21/336

(52) U.S. Cl. 438/261; 257/E21.422

(57) ABSTRACT

A flash memory device fabricating method can include forming a plurality of gate patterns over a semiconductor substrate, forming a first spacer over the semiconductor substrate and against sidewalls of each gate pattern and a second spacer over the first spacer, forming an impurity region in the semiconductor substrate and between respective gate patterns, removing the second spacer, and then forming a pre-metal dielectric film over the semiconductor substrate including the gate patterns and the first spacer. The second space can be removed in order to expand a space between the gate patterns to thereby prevent generation of voids between the gate patterns.

The present application claims priority under 35 U.S.C. 119 to Korean Patent Application No. 10-2006-0131514, filed on 21 Dec. 2006, which is hereby incorporated by reference in its entirety.

### BACKGROUND

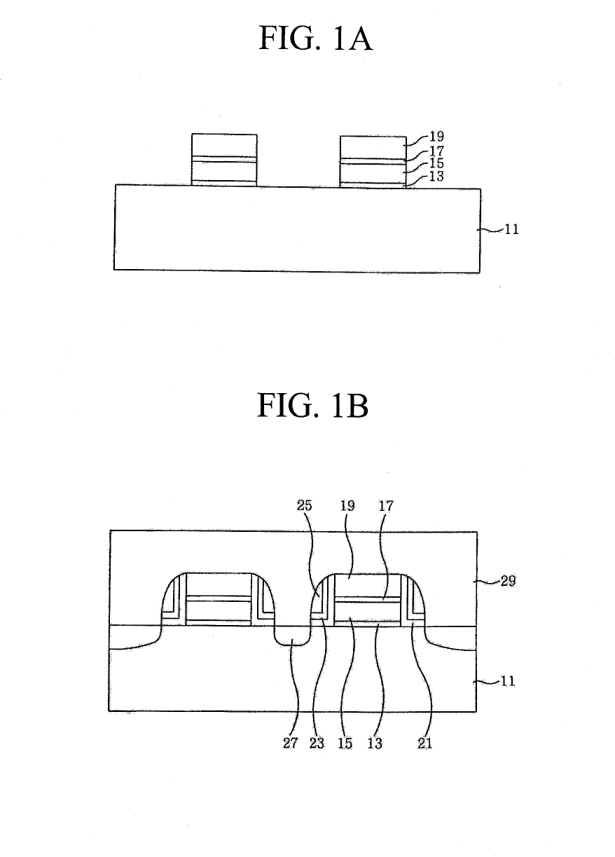

As illustrated in example FIG. 1A, first gate insulating film 13 may be formed on and/or over semiconductor substrate 11 via a thermal oxidation method or the like. First polycrystalline silicon film 15, second gate insulating film 17 and second polycrystalline silicon film 19 may then be sequentially formed on and/or over first insulating film 13. Second gate insulating film 17 may have an ONO (oxide film/nitride film/oxide film) structure.

Second polycrystalline silicon film 19, second gate insulating film 17, first polycrystalline silicon film 15, and first gate insulating film 13 may then be patterned by a photolithographic process using a photoresist pattern or the like to form a gate pattern. At this time, as the gate pattern, first polycrystalline silicon film 15 may correspond to a plotting gate and second polycrystalline silicon film 19 may correspond to a control gate.

As illustrated in example FIG. 1B, second gate insulating film 17 may be formed by sequentially depositing an oxide film having a thickness of about 150 to 250 Å, a nitride film having a thickness of about 150 to 250 Å and an oxide film having a thickness of about 500 to 700 Å on and/or over semiconductor substrate 11 by performing a deposition process. Accordingly, the ONO structure may cover the gate pattern including first gate insulating film 13, plotting gate 15, second gate insulating film 17 and control gate 19. Subsequently, the oxide film, nitride film and oxide film may be etched back sequentially by a reactive ion etching to form first spacer 21, second spacer 23, and third spacer 25 on side walls of the gate pattern.

Additionally, an ion implantation process may be performed using the gate pattern and the first spacer 21, second spacer 23 and third spacer 25 as masks to ion implant impurities into semiconductor substrate 11, thereby forming impurity region 27. First spacer 21, second spacer 23 and third spacer 25 may function to separate impurity region 27 at both sides of the gate pattern such that they are not overlapped.

Next, BPSG (boro-phospho silicate glass), USG (undoped silicate glass), PSG (phospho-silicate glass), BSG (boro-silicate glass) or FSG (fluorine-doped silicate glass) may be deposited by CVD (chemical vapor deposition) or the like to cover the gate pattern, thereby forming pre-metal dielectric (PMD) film 29 on and/or over semiconductor substrate 11.

However, the above-mentioned structure may be disadvantageous in that the first, second and third spacers formed on the sidewalls of the gate pattern have a narrow space between the adjacent gate patterns. Thereby, voids may be generated between the gate patterns when forming the pre-metal dielectric film.

### SUMMARY

Embodiments relate to a method for fabricating a flash memory device capable of preventing void generation in an interlayer insulating film between adjacent gate patterns.

Embodiments relate to a method for fabricating a flash memory device capable of preventing void generation between gate patterns when forming a pre-metal dielectric film.

Embodiments relate to a method for fabricating a flash memory device including at least one of the following steps: forming a pair of gate patterns each having a multilayer structure including a first gate insulating film, a plotting gate, a second gate insulating film, and a control gate over a semiconductor substrate; forming a first spacer and a second spacer on sidewalls of each gate pattern; forming an impurity region by ion-implanting impurities into a predetermined region of the semiconductor substrate using the gate patterns, the first spacer and the second spacer as masks; removing one of the first spacer and the second spacer; and then forming a pre-metal dielectric film over the semiconductor substrate including the gate patterns and the remaining one of the first spacer and the second spacer.

Embodiments relate to a method for fabricating a flash memory device including at least one of the following steps: forming a first gate insulating film over a semiconductor substrate; sequentially forming a first polycrystalline silicon film, a second gate insulating film, and a second polycrystalline silicon film over the semiconductor substrate including the first gate insulating film; forming a first spacer over the semiconductor substrate and against sidewalls of the first gate insulating film, the first polycrystalline silicon film, the second gate insulating film, and the second polycrystalline silicon film; forming a second spacer over the first spacer; forming an impurity region by ion implanting impurities into a predetermined region of semiconductor substrate using the first spacer and second spacer as masks; removing the second spacer; and then forming a pre-metal dielectric film over the semiconductor substrate.

Embodiments relate to a method for fabricating a flash memory device including at least one of the following steps: forming a plurality of gate patterns over a semiconductor substrate; forming a first spacer over the semiconductor substrate and against sidewalls of each gate pattern and a second spacer over the first spacer; forming an impurity region in the semiconductor substrate and between adjacent gate patterns; removing the second spacer; and then forming a pre-metal dielectric film over the semiconductor substrate including the gate patterns and the first spacer.

### DRAWINGS

Example FIGS. 1A to 1B illustrate a method for fabricating a flash memory device.

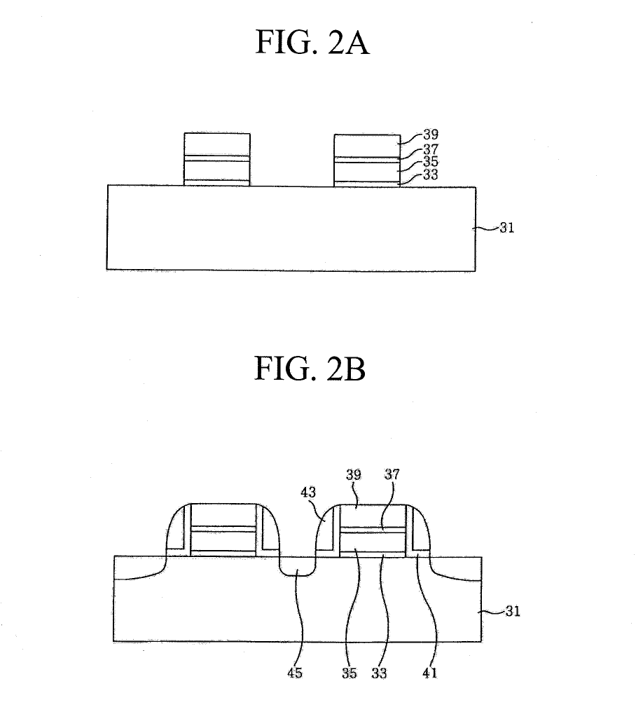

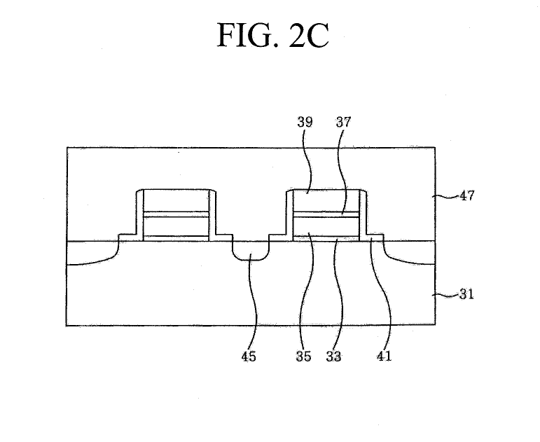

Example FIGS. 2A to 2C illustrate a method for fabricating a flash memory device, in accordance with embodiments.

### DESCRIPTION

As illustrated in example FIG. 2A, a method for fabricating a flash memory device in accordance with embodiments can include forming first gate insulating film 33 on and/or over semiconductor substrate 31. First gate insulating film 33 may be formed using a thermal oxidation method or the like. A deposition process can then be performed to sequential form first polycrystalline silicon film 35, second gate insulating film 37, and second polycrystalline silicon film 39 on and/or over first gate insulating film 33.

Next, a photoresist material may then be coated on and/or over the overall surface of semiconductor substrate 31, and then an exposure and development process is performed to form a photoresist pattern having an arbitrary pattern for forming a gate. A patterning process such as an etching process using the photoresist pattern as an etching mask can then be performed to sequentially remove a portion of second polycrystalline silicon film 39, second gate insulating film 37, first polycrystalline silicon film 35, and first gate insulating film 33, thereby completing a gate pattern having a multilayer structure including first gate insulating film 33, plotting gate 35, second gate insulating film 37, and control gate 39.

First polycystalline silicon film 35 can correspond to the plotting gate of the gate pattern structure, and second polycrystalline silicon film 39 can correspond to the control gate of the gate pattern structure. Second gate insulating film 37 can have an ONO (oxide film/nitride film/oxide film) structure. Additionally, first gate insulating film 33 can function as a tunnel oxide film.

As illustrated in example FIG. 2B, a sequential deposition process can then be performed to deposit an oxide film and a nitride film sequentially on and/or over the gate pattern to provide a multilayer structure including first gate insulating film 33, plotting gate 35, second gate insulating film 37, and control gate 39. The oxide film can have a thickness of between about 150 to 250 Å and the nitride film can have a thickness of between about and 500 to 1000 Å.

A sequential etching back process using a reactive ion etching (RIE) or the like can then be performed to remove a portion of the oxide film and nitride film so as to expose the uppermost surface of semiconductor substrate 31. Thereby, first spacer 41 and second spacer 43 can be formed on the sidewalls of the gate pattern. Particularly, second spacer 43 can be formed on and/or over first spacer 41.

An ion implantation process using the gate pattern and first spacer 41 and second spacer 43 as masks can then be performed to form impurity region 45 by ion implanting impurities into a predetermined region of semiconductor substrate 31. First spacer 41 and second spacer 43 can serve to prevent impurities from being implanted into semiconductor substrate 31 thereby functioning to separate, and not overlap, impurity region 45 at both sides of the gate pattern.

As illustrated in example FIG. 2C, second spacer 43 can then be removed by being selectively etched using a wet etching process with phosphoric acid (H₃PO₄) at a temperature of between 150 to 200° C. for about 10 to 20 minutes. The etching process can be performed to expand space between the gate patterns by two-fold of the thickness of second spacer 43.

Second spacer 43 may alternatively be removed using a chemical downstream (CD) dry etching process under the following process conditions: at normal temperature, microwave power of 50 to 1000 W, pressure of 10 to 1000 pascal, O₂ gas at a flow rate of 50 to 500 sccm, CF₄ gas at a flow rate of 100 to 500 sccm, and N₂ gas at a flow rate of 10 to 100 sccm for about 10 to 100 seconds.

A deposition process such as chemical vapor deposition (CVD) or the like can then be performed to cover the gate pattern completely with the deposition of at least one of BPSG, USG, PSG, BSG, and FSG on and/or over semiconductor substrate 31, thereby forming pre-metal dielectric (PMD) film 47.

At this time, in accordance with embodiments, voids are not generated between the gate patterns when forming pre-metal dielectric film 47 because the space between the gate patterns is expanded by removing second spacer 43 via the above-mentioned etching process. Meaning, void generation between the gate patterns can be prevented since the void generation results from the density of the gate patterns.

In accordance with embodiments, first spacer 41 and second spacer 43 can be formed on the sidewalls of the gate pattern, an ion implantation process can then be performed using the gate pattern, and then removing second spacer 43 to expand a space between the gate patterns. Therefore, the void generation between the gate patterns can be prevented when forming thick pre-metal dielectric film 47 that completely covers the gate pattern in subsequent processes.

As apparent from the above description, in accordance with the present invention, the method for fabricating a flash memory device performs ion implantation process using spacers, then removes a portion of the spacers so as to expand a space between the gate patterns, and then forms the pre-metal dielectric film. Thereby, void generation between the gate patterns can be effectively prevented, and, as a result, the reliability of the flash memory device products can be improved.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
forming a pair of gate patterns each having a multilayer structure including a first gate insulating film, a plotting gate, a second gate insulating film, and a control gate over a semiconductor substrate;
forming a first spacer and a second spacer on sidewalls of each gate pattern;
forming an impurity region by ion-implanting impurities into a predetermined region of the semiconductor substrate using the gate patterns, the first spacer and the second spacer as masks;
removing one of the first spacer and the second spacer; and then
forming a pre-metal dielectric film over the semiconductor substrate including the gate patterns and the remaining one of the first spacer and the second spacer.

2. The method of claim 1, wherein the first spacer comprises an oxide film.

3. The method of claim 2, wherein the oxide film has a thickness of between 150 to 250 Å.

4. The method of claim 1, wherein the second spacer comprises a nitride film.

5. The method of claim 4, wherein the nitride film has a thickness of between 500 to 1000 Å.

6. The method of claim 1, wherein in the step of removing at least one of the first spacer and the second spacer, only the second spacer is removed.

7. The method of claim 6, wherein the second spacer is removed using a wet etching process.

8. The method of claim 7, wherein the wet etching process uses phosphoric acid (H₃PO₄).

9. The method of claim 8, wherein the wet etching process is performed at a temperature in the range of between 150 to 200° C. and for about 10 to 20 minutes.

10. The method of claim 6, wherein the second spacer is removed using a dry etching process.

11. The method of claim 10, wherein the dry etching process comprises a chemical downstream dry etching process.

12. The method of claim 11, wherein the chemical downstream dry etching process is performed for about 10 to 100 seconds at normal temperature, a microwave power of 50 to 1000 W and a pressure of 10 to 1000 pascal, using O₂ gas at a flow rate of 50 to 500 sccm, CF₄ gas at a flow rate of 100 to 500 sccm, and N₂ at a flow rate of 10 to 100 sccm.

13. A method comprising:
forming a first gate insulating film over a semiconductor substrate;
sequentially forming a first polycrystalline silicon film, a second gate insulating film, and a second polycrystalline silicon film over the semiconductor substrate including the first gate insulating film;
forming a first spacer over the semiconductor substrate and against sidewalls of the first gate insulating film, the first polycrystalline silicon film, the second gate insulating film, and the second polycrystalline silicon film;
forming a second spacer over the first spacer;
forming an impurity region in a predetermined region of the semiconductor substrate by ion implanting impurities into the predetermined region of semiconductor substrate using the first spacer and second spacer as masks;
removing the second spacer; and then
forming a pre-metal dielectric film over the semiconductor substrate.

14. The method of claim 13, wherein the first gate insulating film is formed using a thermal oxidation method.

15. The method of claim 13, wherein the first polycystalline silicon film corresponds to a plotting gate of a gate pattern structure, and the second polycrystalline silicon film corresponds to a control gate of the gate pattern structure.

16. The method of claim 13, wherein the second gate insulating film has an ONO structure.

17. The method of claim 13, wherein the first gate insulating film comprises a tunnel oxide film.

18. A method comprising:
forming a plurality of gate patterns over a semiconductor substrate;
forming a first spacer over the semiconductor substrate and against sidewalls of each gate pattern and a second spacer over the first spacer;
forming an impurity region in the semiconductor substrate and between adjacent gate patterns;
removing the second spacer; and then
forming a pre-metal dielectric film over the semiconductor substrate including the gate patterns and the first spacer.

19. The method of claim 18, wherein each gate pattern comprises a first gate insulating film, a plotting gate formed over the first gate insulating film, a second gate insulating film formed over the plotting gate, and a control gate formed over the second gate insulating film.

20. The method of claim 18, wherein removing the second spacer comprises using a chemical downstream dry etching process at normal a temperature, a microwave power of 50 to 1000 W, a pressure of 10 to 1000 pascal, O₂ gas at a flow rate of 50 to 500 sccm, CF₄ gas at a flow rate of 100 to 500 sccm, and N₂ at a flow rate of 10 to 100 sccm for about 10 to 100 seconds.
